(19) United States
(12) Patent Application Publication
(10) Pub. No.: US 2025/0100023 A1
(43) Pub. Date: Mar. 27, 2025

(54) SUBSTRATE PROCESSING DEVICE AND SUBSTRATE PROCESSING METHOD

(71) Applicant: SCREEN Holdings Co., Ltd., Kyoto (JP)

(72) Inventors: Akira ITO, Kyoto-shi (JP); Yasuhiko NAGAI, Kyoto-shi (JP); Takashi AKIYAMA, Kyoto-shi (JP); Shigeru YAMAMOTO, Kyoto-shi (JP); Keiji IWATA, Kyoto-shi (JP)

(21) Appl. No.: 18/890,972

(22) Filed: Sep. 20, 2024

(30) Foreign Application Priority Data
Sep. 21, 2023 (JP) 2023-155672

(51) Int. Cl. B08B 3/08; B08B 3/10

(52) U.S. Cl. CPC B08B 3/08; B08B 3/10

(57) ABSTRACT

A solvent supply unit of a substrate processing device is disposed at a position higher than an opening of an upper surface of a processing tank, and supplies a mist-like solvent from an outside of the processing tank toward an inside of the processing tank in plan view. When a substrate is immersed in processing liquid, a control unit performs a solvent supply operation of decompressing an inside of the chamber and supplying the mist-like solvent from the solvent supply unit. In a solvent supply state in which the inside of the chamber is decompressed and the solvent is supplied, the control unit causes a lifter to take out the substrate from the processing liquid in the processing tank, and then opens a QDR valve to discharge the processing liquid from the processing tank. In the solvent supply state, the control unit causes the lifter to lower the substrate to a lower position in the processing tank in which the processing liquid is not stored, and then causes the lifter to raise the substrate.

### CROSS-REFERENCE TO RELATED APPLICATIONS

This application claims priority to Japanese Patent Application No. 2023-155672 filed Sep. 21, 2023, the subject matter of which is incorporated herein by reference in entirety.

### BACKGROUND

### Technical Field

The present invention relates to a substrate processing device and a substrate processing method for processing a substrate. Examples of the substrate include a semiconductor substrate, a substrate for a flat panel display (FPD), a glass substrate for a photomask, a substrate for an optical disk, a substrate for a magnetic disk, a ceramic substrate, and a substrate for a solar cell. Examples of the FPD include a liquid crystal display device and an organic electroluminescence (EL) display device.

### Related Art

A conventional substrate processing device includes a chamber, a processing tank installed in the chamber, and a holding unit that holds a substrate (see, for example, JP 2023-020268 A). The processing tank stores processing liquid. The substrate held by the holding unit is lifted up and down between a lower position in the processing tank and an upper position in the chamber and above the processing tank.

The substrate processing device includes a solvent discharging unit and a water-repellent agent discharging unit. The solvent discharging unit and the water-repellent agent discharging unit are each disposed in the chamber. The solvent discharging unit discharges vapor of isopropyl alcohol (IPA). The water-repellent agent discharging unit discharges water-repellent agent vapor.

The substrate held by the holding unit is immersed in the processing liquid in the processing tank. Thereafter, the inside of the chamber is depressurized, and the IPA vapor is discharged into the chamber from the solvent discharging unit. In this state, the substrate is pulled up to the upper side of the processing tank. As a result, the substrate is exposed to the atmosphere of the IPA vapor, whereby the processing liquid adhered to the substrate is replaced with IPA (solvent). Then, the water-repellent agent vapor is discharged from the water-repellent agent discharging unit into the chamber.

### SUMMARY

However, the IPA vapor hardly adheres to the substrate, and there is a possibility that the replacement processing with IPA (solvent) becomes insufficient. For example, when processing liquid (for example, pure water) remains on the substrate, a water repellent processing (silylation processing) becomes insufficient. Therefore, pattern collapse cannot be satisfactorily prevented.

The present invention has been made in view of such circumstances, and an object thereof is to provide a substrate processing device and a substrate processing method capable of easily attaching a solvent to a substrate.

In order to achieve such an object, the present invention has the following configuration. That is, a substrate processing device for processing a substrate according to the present invention includes: a processing tank that stores processing liquid; a chamber that accommodates the processing tank; a decompression pump that decompresses an inside of the chamber; a lifter that lifts the substrate up and down in the chamber while holding the substrate; an on-off valve that discharges the processing liquid from the processing tank; a solvent supply unit that is provided in the chamber, the solvent supply unit being disposed at a position higher than an opening formed in an upper surface of the processing tank, and supplying at least one of a mist-like solvent and a droplet-like solvent from an outside of the processing tank toward an inside of the processing tank in plan view; and a control unit. The control unit performs a solvent supply operation of causing the decompression pump to decompress the inside of the chamber and supplying at least one of the mist-like solvent and the droplet-like solvent from the solvent supply unit when the substrate is immersed in the processing liquid. The control unit causes the lifter to take out the substrate from the processing liquid in the processing tank in a solvent supply state in which the inside of the chamber is decompressed and the solvent is supplied, and then opens the on-off valve to discharge the processing liquid from the processing tank. The control unit performs, in the solvent supply state, a substrate lifting operation of causing the lifter to lower the substrate to a position in the processing tank where the processing liquid is not stored, and then causing the lifter to raise the substrate.

According to the substrate processing device of the present invention, at least one of the mist-like solvent and the droplet-like solvent is supplied from the solvent supply unit. As a result, after the substrate is taken out from the processing liquid stored in the processing tank, the solvent can be more easily attached to the substrate than the solvent vapor. Therefore, the solvent can be efficiently attached to the substrate.

In addition, in the above-described substrate processing device, the substrate lifting operation preferably causes, in the solvent supply state, the lifter to lower the substrate to a position in the processing tank, makes the lifter to cause the substrate to stand by for a preset lower standby time at a position in the processing tank, then causes the lifter to raise the substrate, and makes the lifter to cause the substrate to stand by for a preset upper standby time at a position at which the substrate is raised. The lower standby time is preferably longer than the upper standby time.

For example, when the mist-like solvent is supplied, the substrate is lifted up and down in order to suppress adhesion unevenness of the solvent. At this time, the lower standby time for causing the substrate to stand by at the position in the processing tank is made longer than the upper standby time for causing the substrate to stand by at the position where the substrate is raised. This is because, for example, when a mist-like solvent is supplied, an amount of the solvent adhering to the substrate is larger when the substrate is disposed at the position in the processing tank than when the substrate is disposed at the position in the chamber and above the processing tank. As a result, the solvent can be more efficiently attached to the substrate. That is, a consumption amount of the solvent can be reduced, and a processing time can be shortened.

In addition, in the above-described substrate processing device, the substrate lifting operation is preferably performed a plurality of times. As the substrate lifting operation is repeated, the adhesion unevenness of the solvent can be further suppressed.

In addition, the above-described substrate processing device further includes a water-repellent agent nozzle that supplies water-repellent agent vapor into the chamber. The control unit preferably causes the water-repellent agent nozzle to supply the water-repellent agent vapor to the substrate after the substrate lifting operation is performed and after supplying of the solvent is stopped.

Since at least one of the mist-like solvent and the droplet-like solvent is supplied from the solvent supply unit, the solvent can be easily adhered to the substrate. Therefore, it is possible to prevent the processing liquid from remaining on the substrate due to insufficient replacement processing with the solvent. In addition, the processing liquid remaining on the substrate prevents the water-repellent agent from adhering to the substrate. Since the replacement processing with the solvent can be sufficiently performed, the water repellent processing with the water-repellent agent can be favorably performed.

In addition, in the above-described substrate processing device, after supplying of the water-repellent agent vapor is stopped, the control unit preferably performs a second solvent supply operation of causing the decompression pump to decompress the inside of the chamber and supplying at least one of the mist-like solvent and the droplet-like solvent from the solvent supply unit. This makes it possible to wash away the water-repellent agent and particles derived from the water-repellent agent.

In addition, in the above-described substrate processing device, the second solvent supply operation is preferably performed when the lifter causes the substrate to stand by at a position in the processing tank where the processing liquid is not stored. When the water-repellent agent or the like is washed away, an amount of the solvent adhering to the substrate can be increased.

In addition, in the above-described substrate processing device, the control unit preferably causes the lifter to lower the substrate to a position in the processing tank when the second solvent supply operation is being performed, makes the lifter to cause the substrate to stand by for a preset second lower standby time at a position in the processing tank, then causes the lifter to raise the substrate, and makes the lifter to cause the substrate to stand by for a preset second upper standby time at a position at which the substrate is raised. The second lower standby time is preferably longer than the second upper standby time.

For example, when the mist-like solvent is supplied, the substrate is lifted up and down in order to suppress adhesion unevenness of the solvent. At this time, the second lower standby time for causing the substrate to stand by at the position in the processing tank is made longer than the second upper standby time for causing the substrate to stand by at the position where the substrate is raised. This is because, for example, when the mist-like solvent is supplied, the amount of the solvent adhering to the substrate is larger when the substrate is disposed at the position in the processing tank than when the substrate is disposed at the position in the chamber and above the processing tank. As a result, the solvent can be more efficiently attached to the substrate. That is, a consumption amount of the solvent can be reduced, and a processing time can be shortened.

A substrate processing method according to the present invention is a substrate processing method of a substrate processing device. The substrate processing device includes: a processing tank that stores processing liquid; a chamber that accommodates the processing tank; a decompression pump that decompresses an inside of the chamber; a lifter that lifts a substrate up and down in the chamber while holding the substrate; and an on-off valve that discharges the processing liquid from the processing tank. The substrate processing method includes: a solvent supply step of causing the decompression pump to decompress the inside of the chamber and supplying at least one of a mist-like solvent and a droplet-like solvent from a solvent supply unit when the substrate is immersed in the processing liquid; a substrate extraction step of causing the lifter to take out the substrate from the processing liquid in the processing tank in a solvent supply state in which the inside of the chamber is decompressed and the solvent is supplied; a processing liquid discharge step of discharging the processing liquid from the processing tank by opening the on-off valve in the solvent supply state and after the substrate extraction step is performed; and a substrate lifting step of causing the lifter to lower the substrate to a position in the processing tank where the processing liquid is not stored in the solvent supply state, and then causing the lifter to raise the substrate. The solvent supply unit is provided in the chamber. The solvent supply unit is disposed at a position higher than an opening formed in an upper surface of the processing tank, and supplies at least one of the mist-like solvent and the droplet-like solvent from an outside of the processing tank toward an inside of the processing tank in plan view.

According to the substrate processing device and the substrate processing method according to the present invention, a solvent can be easily attached to a substrate.

### BRIEF DESCRIPTION OF DRAWINGS

For the purpose of illustrating the invention, there are shown in the drawings several forms which are presently preferred, it being understood, however, that the invention is not limited to the precise arrangement and instrumentalities shown.

FIG. 1 is a longitudinal sectional view illustrating a schematic configuration of a substrate processing device according to a first embodiment;

FIG. 2 is a plan view illustrating mist nozzles of two solvent supply units;

FIG. 3 is a diagram for explaining the operation of the substrate processing device according to the first embodiment;

FIG. 4 is a timing chart illustrating the operation of the substrate processing device according to the first embodiment;

FIG. 5 is a timing chart for explaining three substrate lifting operations in a solvent supply state;

FIG. 6A is a diagram of an experimental result in which the amount of IPA adhered to the substrate is compared under four conditions when mist-like IPA is supplied, FIG. 6B is a diagram illustrating a state in which the substrate is disposed at an upper position above the processing tank, and FIG. 6C is a diagram illustrating a state in which the substrate is disposed at a lower position in the processing tank;

FIG. 7 is a diagram for explaining step S08A according to a second embodiment;

FIGS. 8A and 8B are timing charts for explaining the operation of the substrate processing device according to the second embodiment; and

FIG. 9 is a longitudinal sectional view illustrating a schematic configuration of a substrate processing device according to a third embodiment.

### DETAILED DESCRIPTION

### First Embodiment

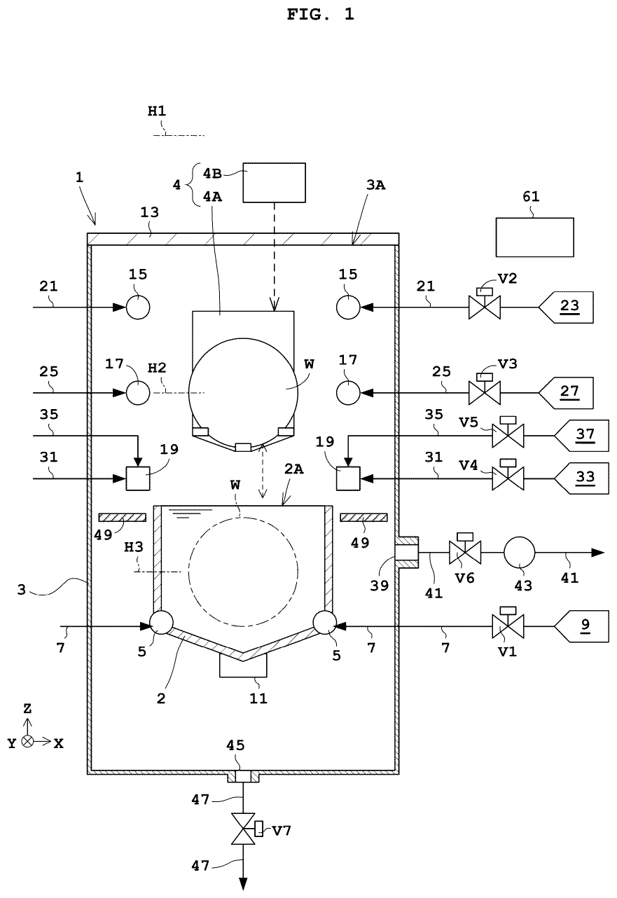

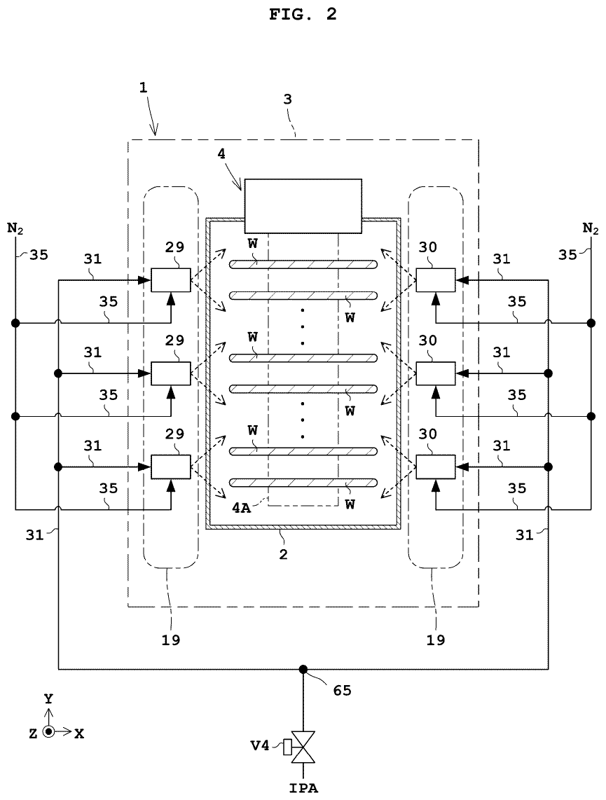

Hereinafter, a first embodiment of the present invention will be described with reference to the drawings. FIG. 1 is a longitudinal sectional view illustrating a schematic configuration of a substrate processing device 1 according to the first embodiment. FIG. 2 is a plan view illustrating mist nozzles 29 and 30 of two solvent supply units 19.

(1) Configuration of Substrate Processing Device Refer to FIG. 1. The substrate processing device 1 performs drying processing on a plurality of (for example, fifty or twenty-five) substrates W. Each substrate W is formed in, for example, a disk shape. On the front face (principal plane) of each substrate W, for example, a pattern such as an element is formed. In this case, the face opposite to the front face of the substrate W is referred to as a back face.

The substrate processing device 1 includes a processing tank 2 that stores processing liquid, a chamber 3 that houses the processing tank 2, a lifter 4, and two ejection pipes 5. The processing tank 2 is disposed at a lower portion in the chamber 3 and is disposed away from a bottom surface in the chamber 3. An opening 2A is formed on the upper surface of the processing tank 2. The processing liquid overflowing from the opening 2A is stored in the bottom portion of the chamber 3.

The lifter 4 lifts the plurality of substrates W up and down in the chamber 3 while holding the plurality of substrates W. The lifter 4 includes a holding unit (holder) 4A that holds the plurality of substrates W in a vertical posture, and a lift unit 4B that lifts the holding unit 4A up and down in the vertical direction (Z direction). The plurality of substrates W held by the holding unit 4A are arranged at equal intervals in the thickness direction of each substrate W. For example, in FIG. 1, the direction in which the plurality of substrates W are aligned is a Y direction.

The lift unit 4B includes, for example, an electric motor. The lift unit 4B can move the plurality of substrates W held by the holding unit 4A to, for example, a transfer position H1 above the chamber 3, an upper position H2 above the processing tank 2 in the chamber 3, and a lower position (immersion processing position) H3 in the processing tank 2. The upper position H2 is preferably a position where the lower end of each substrate W is higher than two solvent supply units 19 described later. The upper position H2 may be a height position at which the two solvent supply units 19 are disposed between the center of each substrate W and the lower end of each substrate W.

Two ejection pipes 5 for supplying the processing liquid into the processing tank 2 are provided at the bottom portion of the processing tank 2. Each ejection pipe 5 is formed linearly along the Y direction in which the plurality of substrates W are aligned. Each ejection pipe 5 has a plurality of ejection ports arranged in the Y direction.

A tip portion of a processing liquid pipe 7 branches into two. Thus, the two tip portions of the processing liquid pipe 7 are connected to the two ejection pipes 5, respectively. A base end portion of the processing liquid pipe 7 is connected to a processing liquid supply source 9. The processing liquid supply source 9 sends, for example, pure water as processing liquid to the processing liquid pipe 7. As the pure water, for example, deionized water (DIW) is used. An on-off valve V1 is provided in the processing liquid pipe 7. The on-off valve V1 supplies pure water and stops the supply. For example, when the on-off valve V1 is opened, pure water is supplied from the two ejection pipes 5. When the on-off valve V1 is closed, the supply of pure water from the two ejection pipes 5 is stopped.

As the processing liquid, a diluted isopropyl alcohol (IPA) liquid diluted with pure water may be used. Further, the two ejection pipes 5 may be configured to be able to selectively eject pure water and diluted IPA liquid.

The substrate processing device 1 includes a QDR valve 11 provided at the bottom portion of the processing tank 2. The QDR valve 11 discharges processing liquid (for example, pure water) from the processing tank 2. Specifically, the QDR valve 11 discharges the pure water in the processing tank 2 to the bottom surface in the chamber 3. When the QDR valve 11 is opened, the pure water in the processing tank 2 is rapidly discharged to the bottom portion in the chamber 3. When the QDR valve 11 is closed, pure water can be stored in the processing tank 2. Further, the QDR valve 11 corresponds to an on-off valve of the present invention.

The chamber 3 includes an opening 3A through which the plurality of substrates W pass, and an upper cover 13 that closes the opening 3A. The opening 3A is provided in the ceiling portion of the chamber 3. When the upper cover 13 is opened, the plurality of substrates W can pass through the opening 3A. When the upper cover 13 is closed, the space in the chamber 3 is closed.

In addition, the substrate processing device 1 includes two inert gas nozzles 15, two water-repellent agent vapor nozzles 17, and two solvent supply units (two nozzle rows) 19. The two inert gas nozzles 15, the two water-repellent agent vapor nozzles 17, and the two solvent supply units 19 are each provided in the chamber 3. The solvent supply unit 19 corresponds to a solvent supply unit of the present invention. The water-repellent agent vapor nozzle 17 corresponds to a water-repellent agent nozzle of the present invention.

Between the upper cover 13 and the processing tank 2, the two inert gas nozzles 15, the two water-repellent agent vapor nozzles 17, and the two solvent supply units 19 are arranged in this order from the top. A specific description will be given. The two inert gas nozzles 15 are disposed near the upper cover 13. In addition, the two inert gas nozzles 15 are disposed between the upper cover 13 and the two water-repellent agent vapor nozzles 17. The two water-repellent agent vapor nozzles 17 are disposed between the two inert gas nozzles 15 and the two solvent supply units 19.

The two solvent supply units 19 are disposed between the two water-repellent agent vapor nozzles 17 and the processing tank 2. The two solvent supply units 19 are disposed at positions higher than the opening 2A formed in the upper surface of the processing tank 2. The two solvent supply units 19 are disposed near the outer edge of the opening 2A of the processing tank 2, that is, near the upper end of the side wall of the processing tank 2.

Each of the solvent supply units 19 supplies a mist-like solvent from the outside of the processing tank 2 (or the opening 2A) toward the inside of the processing tank 2 in plan view. That is, as illustrated in FIG. 2, the two solvent supply units 19 are disposed on both sides of the processing tank 2 (or the opening 2A) in plan view.

Similarly, the two inert gas nozzles 15 are disposed on both sides of the processing tank 2 in plan view. Similarly, the two water-repellent agent vapor nozzles 17 are disposed on both sides of the processing tank 2 in plan view.

The two inert gas nozzles 15 and the two water-repellent agent vapor nozzles 17 each extend linearly in the Y direction. Each of the inert gas nozzles 15 and the water-repellent agent vapor nozzles 17 is formed in a tubular shape. Each of the inert gas nozzles 15 and the water-repellent agent vapor nozzles 17 has a plurality of discharge ports arranged in the Y direction.

Each of the two inert gas nozzles 15 supplies an inert gas into the chamber 3. A tip portion of a supply pipe 21 branches into two. As a result, the two tip portions of the supply pipe 21 are connected to the two inert gas nozzles 15, respectively, as illustrated in FIG. 1. A base end of the supply pipe 21 is connected to a first inert gas supply source 23. The first inert gas supply source 23 sends, for example, nitrogen gas as an inert gas to the supply pipe 21. The supply pipe 21 is provided with an on-off valve V2. The on-off valve V2 supplies and stops the inert gas.

Each of the two water-repellent agent vapor nozzles 17 supplies water-repellent agent vapor into the chamber 3. A tip portion of a supply pipe 25 branches into two. As a result, the two tip portions of the supply pipe 25 are connected to the two water-repellent agent vapor nozzles 17, respectively. A base end of the supply pipe 25 is connected to a water-repellent agent vapor supply source 27. The water-repellent agent vapor supply source 27 sends the water-repellent agent vapor to the supply pipe 25. The water-repellent agent vapor is generated by evaporating the liquid water-repellent agent by a heater. The water-repellent agent vapor may contain an inert gas (for example, nitrogen gas) as a carrier gas. The supply pipe 25 is provided with an on-off valve V3. The on-off valve V3 supplies and stops the water-repellent agent vapor. The water-repellent agent modifies the surface of the substrate W to have water repellency. As the water-repellent agent, for example, a silicon-based water-repellent agent or a metal-based water-repellent agent is used. The water-repellent agent is also called a silylating agent.

Each of the two solvent supply units 19 supplies a mist-like solvent into the chamber 3. Refer to FIG. 2. The first solvent supply unit 19 includes a plurality of mist nozzles 29 arranged in the Y direction. The second solvent supply unit 19 includes a plurality of mist nozzles 30 arranged in the Y direction. Each of the mist nozzles 29 and 30 includes a two-fluid nozzle. The two-fluid nozzle is a nozzle that mixes a solvent and an inert gas and ejects a mist-like solvent. That is, the solvent is sprayed by the two-fluid nozzle.

A tip portion of a solvent supply pipe 31 is connected to each of the mist nozzles 29 and 30 (solvent supply unit 19). For example, in a case where the solvent supply unit 19 includes six mist nozzles 29 and 30, a tip portion of the solvent supply pipe 31 branches into six. For example, the six tip portions are connected to the six mist nozzles 29 and 30, respectively. A base end of the solvent supply pipe 31 is connected to a solvent supply source 33. The solvent supply source 33 sends, for example, an isopropyl alcohol (IPA) liquid as a solvent (organic solvent). The solvent preferably has hydrophilicity. The solvent supply pipe 31 is provided with an on-off valve V4. The on-off valve V4 supplies the solvent and stops the supply thereof.

In addition, A tip portion of an inert gas supply pipe 35 is connected to each of the mist nozzles 29 and 30 (solvent supply unit 19). Similarly, for example, in a case where the solvent supply unit 19 includes six mist nozzles 29 and 30, a tip portion of the inert gas supply pipe 35 branches into six. For example, the six tip portions of the inert gas supply pipe 35 are connected to the six mist nozzles 29 and 30, respectively. A base end of the inert gas supply pipe 35 is connected to a second inert gas supply source 37. The second inert gas supply source 37 sends, for example, nitrogen gas as an inert gas. The inert gas supply pipe 35 is provided with an on-off valve V5. The on-off valve V5 supplies the inert gas and stops the supply of the inert gas.

In addition, the substrate processing device 1 includes a decompression pump 43. An exhaust port 39 is provided on a side wall of the chamber 3. The exhaust port 39 is disposed below a shield plate 49 described later. An exhaust pipe 41 is connected to the exhaust port 39. The exhaust pipe 41 is provided with an on-off valve V6 and the decompression pump 43 in order from the exhaust port 39 side. The decompression pump 43 exhausts gas in the chamber 3 to decompress the inside of the chamber 3.

A bottom wall of the chamber 3 is provided with a discharge port 45. A discharge pipe 47 is connected to the discharge port 45. The discharge pipe 47 is provided with an on-off valve V7. When the on-off valve V7 is opened, liquid such as processing liquid stored in the bottom portion of the chamber 3 is discharged through the discharge port 45 and the discharge pipe 47. When the on-off valve V7 is closed, the liquid such as the processing liquid is not discharged from the inside of the chamber 3.

In addition, the chamber 3 includes the shield plate 49. The shield plate 49 partitions the upper space and the lower space in the chamber 3. It is provided slightly below the upper edge (or the opening 2A) of the processing tank 2. The shield plate 49 is formed so as to surround the processing tank 2. There are gaps between the shield plate 49 and the outer wall of the processing tank 2 and between the shield plate 49 and the inner wall of the chamber 3. The processing liquid, the gas, and the mist-like solvent flow through the gaps.

The substrate processing device 1 includes a control unit 61 and a storage unit (not illustrated). The control unit 61 controls each component of the substrate processing device 1. The control unit 61 includes one or more processors such as a central processing unit (CPU). The storage unit includes, for example, at least one of a read-only memory (ROM), a random-access memory (RAM), and a hard disk. The storage unit stores a computer program necessary for controlling each component of the substrate processing device 1.

For example, the control unit 61 causes the lifter 4 to lift the plurality of substrates W up and down, or causes the decompression pump 43 to decompress the inside of the chamber 3. In addition, the control unit 61 discharges the processing liquid from the processing tank 2 to the bottom portion of the chamber 3 by opening the QDR valve 11. The control unit 61 operates the on-off valves V4 and V5 to supply the mist-like solvent from the solvent supply unit 19, or operates the on-off valve V3 to supply the water-repellent agent vapor from the water-repellent agent vapor nozzle 17 into the chamber 3.

### (2) Operation of Substrate Processing Device 1

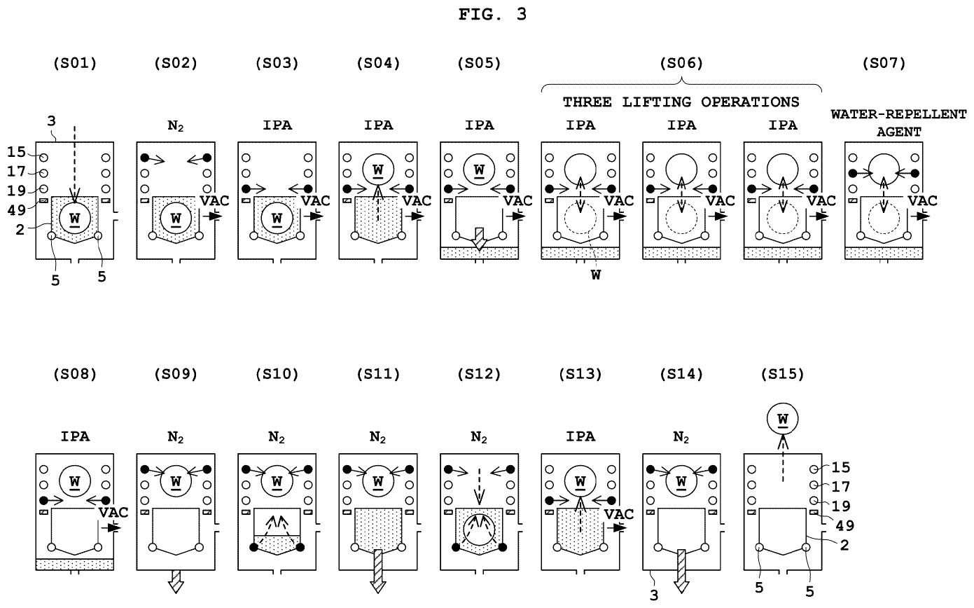

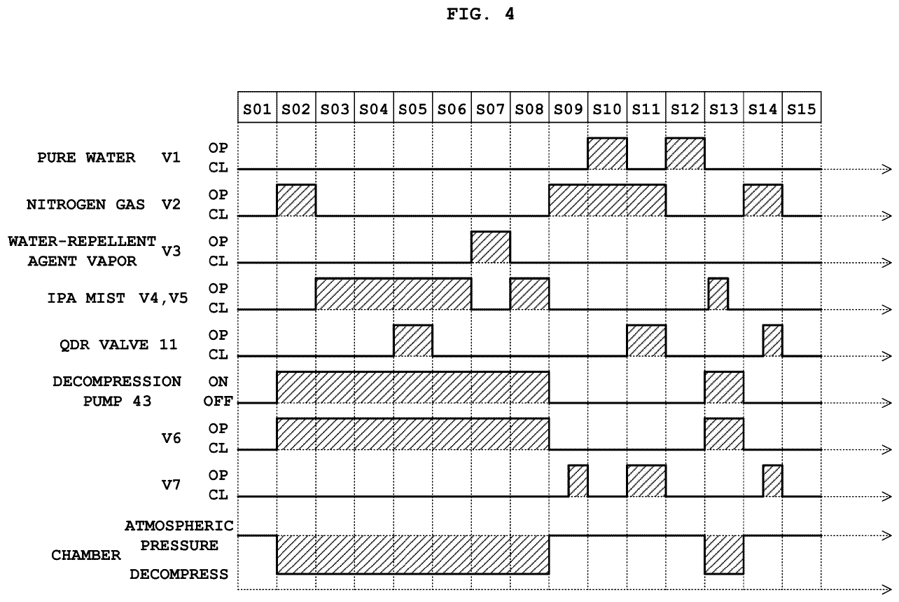

Next, the operation of the substrate processing device 1 will be described with reference to FIGS. 3 and 4. Further, illustration of the lifter 4 is omitted in FIG. 3. In addition, in FIG. 3, an exhaust operation by the decompression pump 43 or the like is indicated by a reference sign VAC. In FIG. 4, reference numeral CL indicates a closed state of the on-off valve V2 and the like, and reference numeral OP indicates an open state of the on-off valve V2 and the like. Hereinafter, the plurality of substrates W will be appropriately described as “substrate W”.

[Step S01] First Immersion Processing (Loading of Substrate into Chamber)

Pure water is stored as processing liquid in the processing tank 2. The pure water is supplied from the ejection pipes 5. The lifter 4 receives a plurality of substrates W from a conveyance robot (not illustrated) at the transfer position H1 by the holding unit 4A. The lifter 4 lowers the substrate W from the transfer position H1 to the lower position H3 in the processing tank 2. That is, the lifter 4 immerses the entire substrate W in the pure water in the processing tank 2. By immersing the substrate W in the pure water, the substrate W is cleaned, and drying of the substrate W is prevented. Thereafter, the opening 3A of the chamber 3 is closed by the upper cover 13.

### [Step S02] Exhaust in Chamber

Thereafter, the on-off valve V2 is opened to supply the nitrogen gas from the inert gas nozzle 15 into the chamber 3. When the substrate W is immersed in the processing liquid, the decompression pump 43 decompresses the inside of the chamber 3. That is, the gas in the chamber 3 is exhausted through the exhaust port 39 and the exhaust pipe 41 by opening the on-off valve V6 while operating the decompression pump 43. As a result, the inside of the chamber 3 is brought into a depressurized state (negative pressure state) where the pressure is lower than the atmospheric pressure.

The decompression pump 43 is operated during steps S02 to S08. Similarly, the on-off valve V6 is opened during steps S02 to S08. Further, during steps S02 to S08 and in step S13, the inside of the chamber 3 is brought into a depressurized state.

### [Step S03] Supply of First IPA (Formation of Mist-Like IPA Atmosphere)

Thereafter, the supply of the nitrogen gas from the inert gas nozzle 15 is stopped by closing the on-off valve V2. When the substrate W is immersed in the processing liquid, the mist-like IPA is supplied from the solvent supply unit 19 while the inside of the chamber 3 is depressurized (solvent supply operation). That is, the mist-like IPA is supplied from the solvent supply unit 19 into the chamber 3 by opening the on-off valves V4 and V5. As a result, the inside of the chamber 3 becomes an atmosphere of the mist IPA. Further, the on-off valves V4 and V5 are opened during steps S03 to S06.

In addition, the mist-like IPA can be contained in the pure water in the processing tank 2. Therefore, it can also be said that the IPA liquid is diluted with pure water in the processing tank 2. As a result, in step S04 described later, when the substrate W is taken out from the pure water containing IPA in the processing tank 2, replacement of the pure water adhering to the substrate W with IPA liquid can be promoted.

### [Step S04] Supply of First IPA (IPA Replacement)

Thereafter, when the inside of the chamber 3 is depressurized and the mist-like IPA is supplied (solvent supply state), the lifter 4 takes out the substrate W from the pure water in the processing tank 2. A specific description will be given. Depressurization in the chamber 3 and supply of mist-like IPA from the solvent supply unit 19 are continued. In such a state, the lifter 4 pulls up the substrate W from the pure water in the processing tank 2. That is, the lifter 4 raises the substrate W from the lower position H3 to the upper position H2.

When the substrate W is exposed to the mist-like IPA, replacement processing in which the pure water adhering to the substrate W is replaced with IPA proceeds.

Further, in step S04, the decompression pump 43 may be stopped and the on-off valve V6 may be closed. In this case, the depressurized state is maintained.

[Step S05] Supply of First IPA (Release of Pure Water from Processing Tank)

Thereafter, the pure water is discharged from the processing tank 2 by opening the QDR valve 11. A specific description will be given. After step S04 is performed, a state (solvent supply state) in which the inside of the chamber 3 is depressurized and the mist-like IPA is supplied is continued. In such a state, the pure water is rapidly discharged from the processing tank 2 to the bottom surface in the chamber 3 by opening the QDR valve 11. After the inside of the processing tank 2 becomes empty, the QDR valve 11 is closed.

### [Step S06] Supply of First IPA (Substrate Lifting Operation)

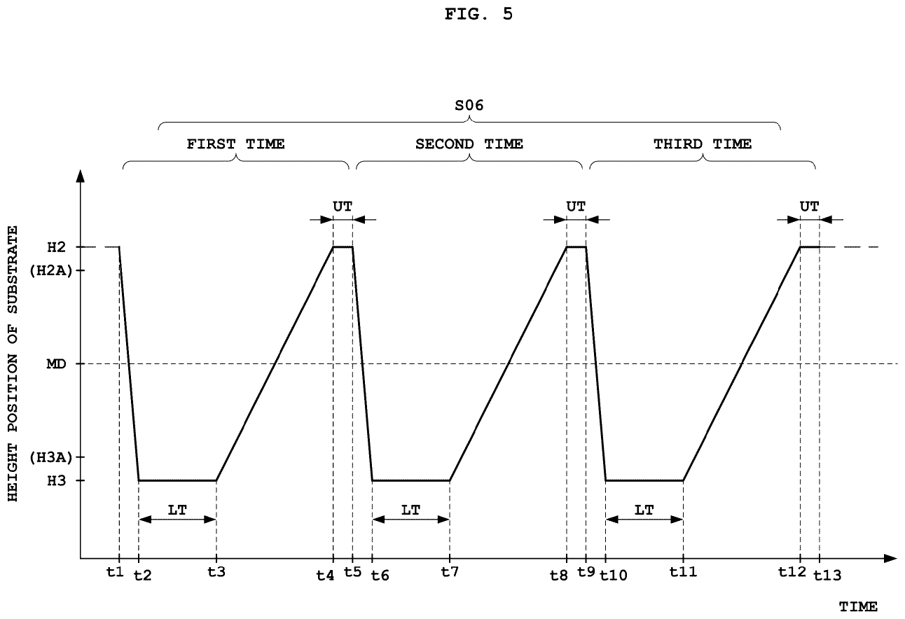

Thereafter, in the solvent supply state, the lifter 4 performs a substrate lifting operation of lowering the substrate W to the lower position H3 in the processing tank 2 where the pure water is not stored, and then raising the substrate W. A specific description will be given. FIG. 5 is a timing chart for explaining three substrate lifting operations in a solvent supply state.

In step S06, the substrate lifting operation is performed three times. In FIG. 5, the first substrate lifting operation is performed between the time points t1 to t5. The second substrate lifting operation is performed between the time points t5 and t9. The third substrate lifting operation is performed between the time points t9 and t13. By performing the substrate lifting operation, the attachment unevenness of the mist-like IPA is suppressed, and the IPA can be uniformly adhered to the substrate W. The three substrate lifting operations perform the same operation. Therefore, the first substrate lifting operation will be described as a representative.

Step S05 is performed before the time point t1 in FIG. 5. At the time point t1 to the time point t2, the lifter 4 lowers the substrate W to the lower position H3 in the processing tank 2. Thereafter, at the time points t2 to t3, the lifter 4 causes the substrate W to stand by at the lower position H3 for a preset lower standby time LT. Thereafter, at the time points t3 to t4, the lifter 4 raises the substrate W to the upper position H2 in the chamber 3 and above the processing tank 2. Thereafter, at the time points t4 to t5, the lifter 4 causes the substrate W to stand by at the upper position H2 at which the substrate W is raised for a preset upper standby time UT. In the substrate lifting operation, the lower standby time LT is set to be longer than the upper standby time UT.

When the lower standby time LT is longer than the upper standby time UT, the IPA is more likely to adhere to the substrate W. Therefore, it is possible to prevent the pure water from remaining on the substrate W due to insufficient replacement processing with IPA. In subsequent step S07, water-repellent agent vapor is supplied. Here, the pure water remaining on the substrate W prevents the water-repellent agent from adhering to the substrate W. This can be prevented by sufficiently performing the replacement processing with IPA.

Thereafter, at the time points t5 to t13, the second and third substrate lifting operations are performed. Thereafter, at the time point t13, the operation of supplying the water-repellent agent vapor in the next step S07 is started. Further, for example, the lowering time (lowering speed) of the time points t1 to t2 is shorter (faster) than the rising time (rising speed) of the time points t3 to t4. In this regard, the lowering time may be the same as or longer than the rising time.

In step S06, the substrate lifting operation is performed three times. In this regard, one substrate lifting operation may be performed. In addition, the substrate lifting operation may be performed twice or four times or more. That is, in step S06, one or more substrate lifting operations may be performed. In FIG. 5, reference numeral MD denotes an intermediate height position (midpoint) between the upper position H2 and the lower position H3. The solvent supply unit 19 may be disposed at or near the height position MD.

### [Step S07] Supply of Water-Repellent Agent Vapor

Thereafter, the exhaust in the chamber 3 is continued. In addition, the supply of the mist-like IPA from the solvent supply unit 19 is stopped by closing the on-off valves V4 and V5. Thereafter, the water-repellent agent vapor is supplied from the water-repellent agent vapor nozzle 17 into the chamber 3 by opening the on-off valve V3. At this time, the lifter 4 lifts the substrate W up and down so that the substrate W passes between the two water-repellent agent vapor nozzles 17. Thus, the water-repellent agent vapor is uniformly supplied to the entire substrate W. The supply of the water-repellent agent vapor replaces the IPA adhering to the substrate W with the water-repellent agent. The water-repellent agent modifies the surface of the substrate W to have water repellency. Further, in steps S04 to S06, the replacement processing with IPA can be sufficiently performed, so that the water repellent processing can be sufficiently performed, thereby satisfactorily preventing pattern collapse.

### [Step S08] Supply of Second IPA

After the supply of the water-repellent agent vapor is stopped, the mist-like solvent is supplied from the solvent supply unit 19 (second solvent supply operation). This operation will be specifically described. After step S07, the exhaust in the chamber 3 is continued. The supply of the water-repellent agent vapor from the water-repellent agent vapor nozzle 17 is stopped by closing the on-off valve V3. In addition, the mist-like IPA is supplied from the solvent supply unit 19 by opening the on-off valves V4 and V5. As a result, the water-repellent agent adhered to the substrate W is replaced with IPA. That is, the water-repellent agent adhered to the substrate W is washed away by the IPA. In addition, the particles derived from the water-repellent agent adhering to the substrate W are washed away by the IPA. The particles are generated, for example, by direct contact between moisture and a water-repellent agent.

### [Step S09] Discharge of Pure Water to Outside of Chamber

Thereafter, the decompression pump 43 is stopped, and the on-off valve V6 is closed. As a result, the exhaust in the chamber 3 is stopped. The supply of the mist-like IPA from the solvent supply unit 19 is stopped by closing the on-off valves V4 and V5. In addition, the nitrogen gas is supplied from the inert gas nozzle 15 into the chamber 3 by opening the on-off valve V2. As a result, the inside of the chamber 3 is returned from the depressurized state to the atmospheric pressure. Thereafter, the pure water stored in the bottom portion in the chamber 3 is discharged to the outside of the chamber 3 through the discharge port 45 and the discharge pipe 47 by opening the on-off valve V7. When all the pure water is discharged from the bottom portion in the chamber 3 (after the chamber 3 becomes empty), the on-off valve V7 is closed. Further, nitrogen gas is supplied during steps S09 to S11.

### [Step S10] Cleaning of Processing Tank (Supply of Cleaning Liquid)

Thereafter, the supply of the nitrogen gas from the inert gas nozzle 15 is continued. In such a state, the pure water is supplied from the ejection pipe 5 into the processing tank 2 as a cleaning liquid by opening the on-off valve V1. The inside of the processing tank 2 is cleaned by the pure water stored in the processing tank 2. Further, when the pure water is stored in the processing tank 2, the pure water supplied from the ejection pipe 5 into the processing tank 2 may overflow from the opening 2A of the processing tank 2.

### [Step S11] Cleaning of Processing Tank (Discharge of Cleaning Liquid)

Thereafter, the supply of the nitrogen gas from the inert gas nozzle 15 is continued. In such a state, the supply of the pure water from the ejection pipe 5 is stopped by closing the on-off valve V1. In addition, the pure water is rapidly discharged from the inside of the processing tank 2 to the bottom surface of the chamber 3 by opening the QDR valve 11. In addition, the pure water (cleaning liquid) stored in the bottom portion of the chamber 3 is discharged by opening the on-off valve V7. After the inside of the processing tank 2 becomes empty, the QDR valve 11 is closed. In addition, after the inside of the chamber 3 becomes empty, the on-off valve V7 is closed.

### [Step S12] Second Immersion Processing

Thereafter, the supply of the nitrogen gas from the inert gas nozzle 15 is continued. In such a state, the on-off valve V1 is opened to supply the pure water from the ejection pipe 5 into the processing tank 2. When a preset amount of pure water is stored in the processing tank 2, the lifter 4 lowers the substrate W from the upper position H2 to the lower position H3. Then, the substrate W is immersed in the pure water in the processing tank 2 for a preset period. As a result, cleaning processing for further removing particles and the like adhering to the substrate W is performed.

### [Step S13] Supply of Third (Final) IPA (Drying Processing)

Thereafter, by closing the on-off valve V1, the supply of the pure water from the ejection pipe 5 is stopped. Thereafter, the gas in the chamber 3 is exhausted by opening the on-off valve V6 while the decompression pump 43 is operated. As a result, the inside of the chamber 3 is brought into a depressurized state. Thereafter, the mist-like IPA is supplied from the solvent supply unit 19 by opening the on-off valves V4 and V5. Thereafter, after the atmosphere in the chamber 3 becomes a mist-like IPA atmosphere, the lifter 4 lifts up the substrate W from the pure water in the processing tank 2. That is, the lifter 4 raises the substrate W from the lower position H3 to the upper position H2. When the substrate W is exposed to the mist-like IPA, the pure water adhering to the substrate W is replaced with IPA.

By closing the on-off valves V4 and V5 in a state in which the exhaust of the inside of the chamber 3 by the decompression pump 43 and the like is continued, the supply of the mist-like IPA from the solvent supply unit 19 is stopped. Since the supply of the mist-like IPA is stopped and the inside of the chamber 3 is depressurized, the IPA adhering to the substrate W is actively volatilized to dry the substrate W. In the drying processing, nitrogen gas may be supplied from the inert gas nozzle 15 after the supply of the mist-like IPA is stopped.

### [Step S14] Supply of Nitrogen Gas

The decompression pump 43 is stopped, and the on-off valve V6 is closed. In addition, the on-off valve V2 is opened to supply the nitrogen gas from the inert gas nozzle 15. As a result, the inside of the chamber 3 is returned from the depressurized state to the atmospheric pressure. Thereafter, by opening the QDR valve 11 and the on-off valve V7, the pure water is discharged from the processing tank 2, and the pure water is discharged from the bottom portion of the chamber 3.

[Step S15] Unloading Substrate from Chamber

The opening 3A is released by opening the upper cover 13. The lifter 4 raises the substrate W held by the holding unit 4A from the upper position H2 to the transfer position H1. The substrate W raised to the transfer position H1 is moved to the next destination by a conveyance robot (not illustrated).

According to the present embodiment, a mist-like solvent (for example, IPA) is supplied from the solvent supply unit 19. As a result, after the substrate W is taken out from the processing liquid (for example, pure water) stored in the processing tank 2, the solvent can be more easily attached to the substrate W than the solvent vapor. Therefore, the solvent can be efficiently attached to the substrate W.

For example, when a mist-like solvent is supplied, the substrate W is lifted up and down in order to suppress adhesion unevenness of the solvent. At this time, the lower standby time LT for causing the substrate W to stand by at the lower position H3 in the processing tank 2 is made longer than the upper standby time UT for causing the substrate W to stand by at the upper position H2 where the substrate W is raised. This is because, for example, when a mist-like solvent is supplied, the amount of the solvent adhering to the substrate W is larger when the substrate W is disposed at the lower position H3 in the processing tank 2 than when the substrate W is disposed at the upper position H2 in the chamber 3 and above the processing tank 2. As a result, the solvent can be more efficiently attached to the substrate W. That is, the consumption amount of the solvent can be reduced, and the processing time can be shortened.

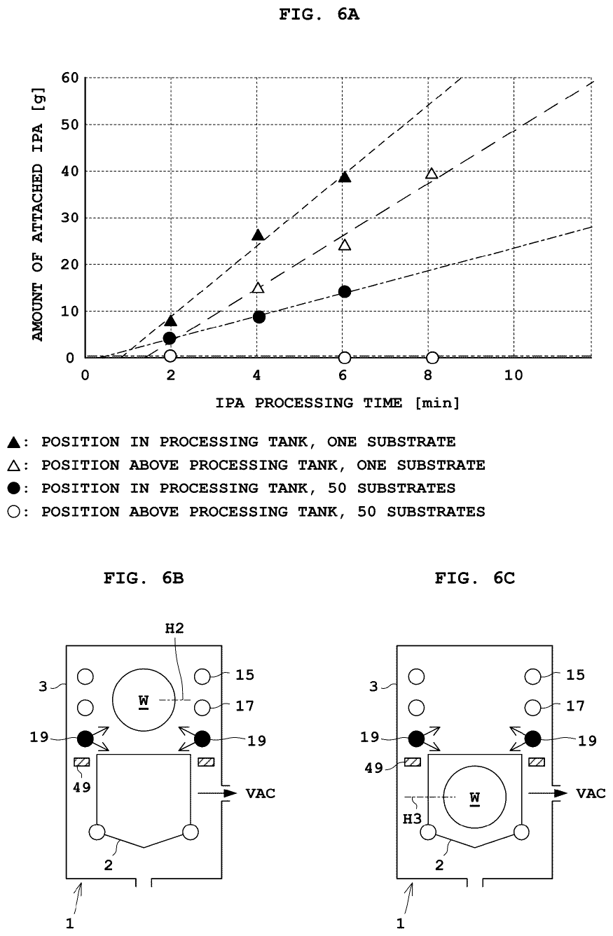

Here, the effect will be supplemented with the experimental results. FIG. 6A is a diagram of an experimental result obtained by comparing the amount of IPA adhered to the substrate W under four conditions when mist-like IPA is supplied. FIG. 6B is a diagram illustrating a state in which the substrate W is disposed at the upper position H2 above the processing tank 2. FIG. 6C is a diagram illustrating a state in which the substrate W is disposed at the lower position H3 in the processing tank 2. In FIGS. 6B and 6C, illustration of the lifter 4 is omitted. In addition, in FIGS. 6B and 6C, the processing tank 2 does not store the processing liquid. Further, in FIG. 6A, the same processing time of IPA means that the supply amount of IPA is the same.

In FIG. 6A, the black triangle mark indicates a result when the mist-like IPA is supplied from the solvent supply unit 19 while one substrate W is disposed at the lower position H3 in the processing tank 2 illustrated in FIG. 6C. In addition, the white triangle mark indicates a result when the mist-like IPA is supplied from the solvent supply unit 19 while one substrate W is disposed at the upper position H2 above the processing tank 2 illustrated in FIG. 6B. Comparison between the two shows that the black triangular mark (lower position H3 in the processing tank 2) has a larger adhesion amount of IPA.

In addition, in FIG. 6A, the black circular mark indicates a result when the mist-like IPA is supplied from the solvent supply unit 19 while fifty substrates W are disposed at the lower position H3 in the processing tank 2 illustrated in FIG. 6C. In addition, the white circular mark is a result when the mist-like IPA is supplied from the solvent supply unit 19 while fifty substrates W are disposed at the upper position H2 above the processing tank 2 illustrated in FIG. 6B. Comparison between the two shows that similarly, the black circular mark (lower position H3 in the processing tank 2) has a larger adhesion amount of IPA.

As described above, it is considered that the reason why the adhesion amount of IPA is larger when the substrate W is disposed at the lower position H3 in the processing tank 2 is that the mist-like IPA tends to remain in the processing tank 2.

The description returns to the effect of the present embodiment. The substrate lifting operation is performed a plurality of times (for example, three times). As the substrate lifting operation is repeated, the adhesion unevenness of the solvent can be further suppressed.

In step S07, the control unit 61 causes the two water-repellent agent vapor nozzles 17 to supply the water-repellent agent vapor to the substrate W. In this respect, the following effects are obtained. Since the mist-like solvent is supplied from the solvent supply unit 19, the solvent can be easily attached to the substrate W. Therefore, it is possible to prevent the processing liquid from remaining on the substrate W due to insufficient replacement processing with the solvent. In addition, the processing liquid remaining on the substrate W prevents the water-repellent agent from adhering to the substrate W. Since the replacement processing with the solvent can be sufficiently performed, the water repellent processing with the water-repellent agent can be favorably performed.

### Second Embodiment

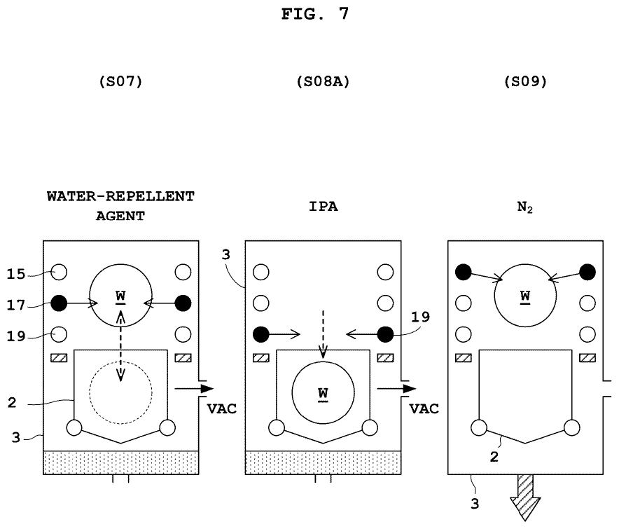

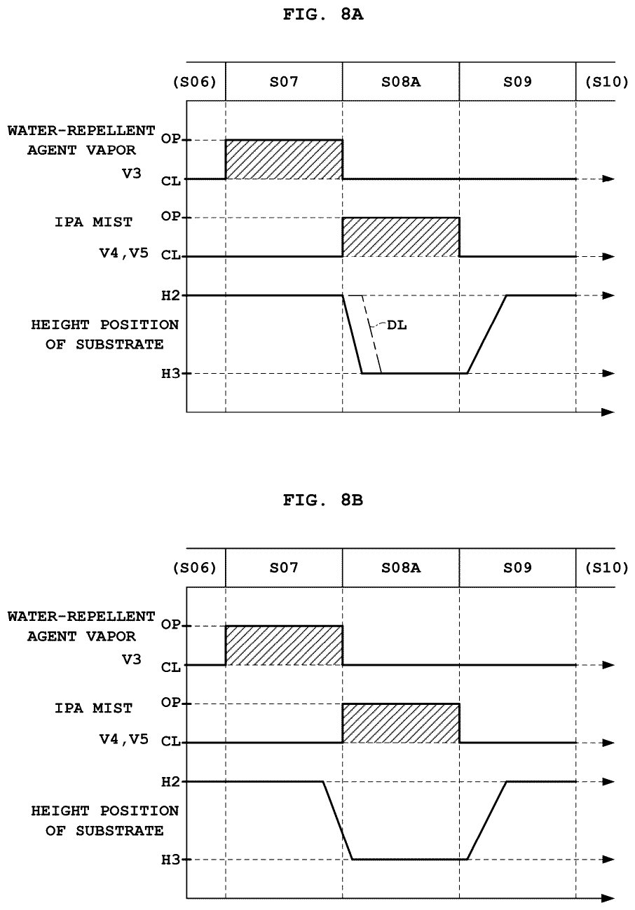

Next, a second embodiment of the present invention will be described with reference to the drawings. Further, the description overlapping with the first embodiment will be omitted. FIG. 7 is a diagram for explaining step S08A according to the second embodiment. FIGS. 8A and 8B are diagrams for explaining the operation of the substrate processing device 1 according to the second embodiment.

In the first embodiment, the IPA adhering to the substrate W has been replaced with a water repellent with water-repellent agent vapor, and then the water repellent has been washed away with mist-like IPA. At this time, the mist-like IPA has been supplied while the substrate W is located at the upper position H2. In this regard, the mist-like IPA may be supplied in a state where the substrate W is located at the lower position H3 of the processing tank 2 in which the processing liquid (for example, pure water) is not stored. That is, step S08A illustrated in FIG. 7 is executed instead of step S08 illustrated in FIG. 3.

### [Step S08A] Supply of Second IPA (Second Solvent Supply Operation)

Refer to FIG. 7. After stopping the supply of the water-repellent agent vapor, the decompression pump 43 decompresses the inside of the chamber 3, and the mist-like solvent is supplied from the solvent supply unit 19 (second solvent supply operation). This operation will be specifically described. After step S07, the exhaust in the chamber 3 is continued. The supply of the water-repellent agent vapor from the water-repellent agent vapor nozzle 17 is stopped by closing the on-off valve V3.

Thereafter, the mist-like IPA is supplied from the solvent supply unit 19 by opening the on-off valves V4 and V5. In addition, the lifter 4 lowers the substrate W from the upper position H2 to the lower position H3. That is, when the lifter 4 causes the substrate W to stand by (position) at the lower position H3 in the processing tank 2 where the processing liquid (for example, pure water) is not stored, the mist-like solvent is supplied from the solvent supply unit 19 (that is, the second solvent supply operation is performed). Since the mist-like IPA is supplied when the substrate W is on standby at the lower position H3, the adhesion amount of the IPA to the substrate W can be increased.

As illustrated in FIG. 8A, the mist-like IPA may be supplied from the solvent supply unit 19 by opening the on-off valves V4 and V5, and at the same time, the lifter 4 may lower the substrate W from the upper position H2 to the lower position H3. In addition, after the mist-like IPA is supplied from the solvent supply unit 19 by opening the on-off valves V4 and V5, the lifter 4 may lower the substrate W to the lower position H3 (see a one-dot chain line indicated by reference sign DL in FIG. 8A).

In addition, as illustrated in FIG. 8B, the mist-like IPA may be supplied from the solvent supply unit 19 by opening the on-off valves V4 and V5 while the lifter 4 is lowering the substrate W toward the lower position H3. In this case, when the water-repellent agent vapor is supplied from the water-repellent agent vapor nozzle 17, the substrate W starts to be lowered toward the lower position H3. After the lifter 4 lowers the substrate W to the lower position H3, that is, when the substrate W is located at the lower position H3, the supply of the mist-like IPA from the solvent supply unit 19 may be started.

As illustrated in FIGS. 8A and 8B, in step S09, the lifter 4 may raise the substrate W from the lower position H3 to the upper position H2.

According to the present embodiment, the control unit 61 performs the second solvent supply operation of causing the decompression pump 43 to decompress the inside of the chamber 3 and supplying the mist-like solvent from the solvent supply unit 19 after stopping the supply of the water-repellent agent vapor. This makes it possible to wash away the water-repellent agent and the particles derived from the water-repellent agent. In addition, the second solvent supply operation is performed when the lifter 4 causes the substrate W to stand by at the lower position H3 in the processing tank 2 where the processing liquid is not stored. When the water-repellent agent or the like is washed away, the amount of the solvent adhering to the substrate W can be increased. Therefore, the solvent can be efficiently attached to the substrate. In addition, as illustrated in FIG. 5, the processing time can be shortened as compared with the case of performing the substrate lifting operation a plurality of times.

### Third Embodiment

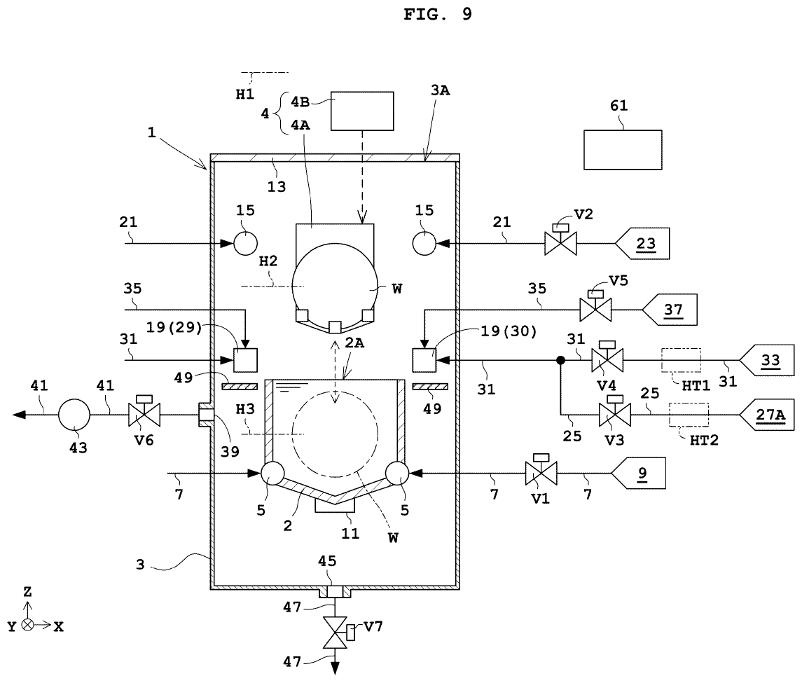

Next, a third embodiment of the present invention will be described with reference to the drawings. Further, description overlapping with the first and second embodiments will be omitted. FIG. 9 is a longitudinal sectional view illustrating a schematic configuration of a substrate processing device 1 according to a third embodiment.

In the first embodiment, the mist nozzles 29 and 30 of the two solvent supply units 19 have supplied a mist-like solvent (for example, IPA). In this regard, in the third embodiment, the mist nozzles 29 and 30 may supply a mist-like water-repellent agent.

Refer to FIG. 9. The substrate processing device 1 does not include the two water-repellent agent vapor nozzles 17 illustrated in FIG. 1. Therefore, the tip of the supply pipe 25 is connected to the solvent supply pipe 31 between the mist nozzles 29 and 30 and the on-off valve V4. Specifically, the tip of the supply pipe 25 is connected to the solvent supply pipe 31 between a branch pipe 65 and the on-off valve V4 illustrated in FIG. 2. The branch pipe 65 is a member that divides the solvent supply pipe 31 into the mist nozzle 29 side and the mist nozzle 30 side.

The base end of the supply pipe 25 is connected to a water-repellent agent supply source 27A. The water-repellent agent supply source 27A sends the liquid of the water-repellent agent to the supply pipe 25. The on-off valve V3 is provided in the supply pipe 25. Further, heaters HT1 and HT2 may be provided between the on-off valve V4 and the solvent supply source 33 and between the on-off valve V3 and the water-repellent agent supply source 27A, respectively. For example, the heater HT2 heats the liquid of the water-repellent agent passing through the supply pipe 25 from the outside of the supply pipe 25 to a preset temperature. Similarly, the heater HT1 heats the solvent to a preset temperature.

With such a configuration, the two solvent supply units (two nozzle rows) 19 can selectively supply the mist-like solvent (for example, IPA) and the mist-like water-repellent agent into the chamber 3.

The operation of the substrate processing device 1 according to the present embodiment will be briefly described. Step S07 illustrated in FIG. 3 shows a state in which the exhaust in the chamber 3 is continued. The supply of the mist-like IPA from the two solvent supply units 19 is stopped by closing the on-off valves V4 and V5. Thereafter, the mist-like water-repellent agent is supplied from the two solvent supply units 19 into the chamber 3 by opening the on-off valves V3 and V5. At this time, the lifter 4 lifts the substrate W up and down so that the substrate W passes between the two solvent supply units 19. The supply of the water-repellent agent vapor replaces the IPA adhering to the substrate W with the water-repellent agent.

In addition, the operation of lifting the substrate W up and down may be performed, for example, similarly to the substrate lifting operation at the time points t1 to t5 illustrated in FIG. 5. That is, in the operation of lifting the substrate W up and down, when the mist-like water-repellent agent is supplied, the substrate W may be lowered to the lower position H3 in the processing tank 2 by the lifter 4, the substrate W may be caused to stand by at the lower position H3 by the lifter 4 for a preset lower standby time LT, and then the substrate W may be raised by the lifter 4, and the substrate W may be caused to stand by at the upper position H2 at which the substrate W is raised for a preset upper standby time UT. In addition, the lower standby time LT is set to be longer than the upper standby time UT. When the supply of the mist-like water-repellent agent is stopped, the on-off valves V3 and V5 are closed.

According to the present embodiment, since the mist-like water-repellent agent is supplied, the water-repellent agent can be more easily attached to the substrate W than water-repellent agent vapor. Therefore, the water-repellent agent can be efficiently attached to the substrate W. In addition, when the substrate W is lifted up and down while the mist-like water-repellent agent is supplied, the lower standby time LT is made longer than the upper standby time UT. As a result, more water-repellent agent can be adhered to the substrate W.

In addition, the solvent and the water-repellent agent can be selectively ejected from the mist nozzles 29 and 30 of the solvent supply unit 19. For example, as illustrated in FIG. 1, two solvent supply units 19 and two water-repellent agent vapor nozzles 17 may be disposed at different heights. When the substrate W is caused to pass between the two solvent supply units 19 during the ejection of the solvent and the substrate W is caused to pass between the two water-repellent agent vapor nozzles 17 during the ejection of the water-repellent agent, the distance by which the substrate W is lifted up and down may be increased. Therefore, the height of the chamber 3 may be increased. However, according to the present embodiment, the height of the chamber 3 can be suppressed.

The present invention is not limited to the above embodiment, and can be modified as follows.

(1) In step S08 of the first embodiment described above, when mist-like IPA is supplied (second solvent supply operation), the substrate W has been located at the upper position H2, and the substrate W has not been lifted up and down. In this regard, when the mist-like IPA is supplied, the lifter 4 may lower the substrate W to the lower position H3 and then raise the substrate W (second substrate lifting operation).

In addition, the second substrate lifting operation in step S08 of the present modification may be performed, for example, similarly to the substrate lifting operation at the time points t1 to t5 illustrated in FIG. 5. That is, in the second substrate lifting operation, when the mist-like IPA is supplied, the substrate W may be lowered to the lower position H3 in the processing tank 2 by the lifter 4, the substrate W may be caused to stand by at the lower position H3 by the lifter 4 for a preset lower standby time LT, and then the substrate W may be raised by the lifter 4, and the substrate W may be caused to stand by at the upper position H2 at which the substrate W is raised for a preset upper standby time UT. In addition, the lower standby time LT is set to be longer than the upper standby time UT.

For example, when a mist-like solvent is supplied, the substrate W is lifted up and down in order to suppress adhesion unevenness of the solvent. At this time, the lower standby time LT for causing the substrate W to stand by at the lower position H3 in the processing tank 2 is made longer than the upper standby time UT for causing the substrate W to stand by at the upper position H2 where the substrate W is raised. This is because, for example, when a mist-like solvent is supplied, the amount of the solvent adhering to the substrate W is larger when the substrate W is disposed at the lower position H3 in the processing tank 2 than when the substrate W is disposed at the upper position H2 in the chamber 3 and above the processing tank 2. As a result, the solvent can be more efficiently attached to the substrate W. That is, the consumption amount of the solvent can be reduced, and the processing time can be shortened. Further, the lower standby time LT in step S08 corresponds to the second lower standby time of the present invention. The upper standby time UT in step S08 corresponds to the second upper standby time of the present invention.

(2) In step S13 of each of the above-described embodiments and modification (1), when the mist-like IPA is supplied, the substrate W has been positioned at the upper position H2, and the substrate W has not been lifted. In this regard, step S13 may be performed as in steps S03 to S06 illustrated in FIGS. 3 and 5. At this time, the substrate lifting operation may be performed once or a plurality of times.

(3) In each of the above-described embodiments and modifications, the two solvent supply units 19 illustrated in FIG. 2 include the mist nozzles 29 and 30. In this regard, the two solvent supply units 19 may include a plurality of shower heads (shower nozzles) for supplying a droplet solvent (for example, IPA) instead of the mist nozzles 29 and 30. Each shower head does not discharge a solvent that is linear and continuous, but discharges droplets. The shower head is also referred to as a one-fluid nozzle. Each solvent supply unit 19 may be configured to supply at least one of a mist-like solvent and a droplet-like solvent.

(4) In each of the above-described embodiments and modifications (1) and (2), the mist nozzles 29 and 30 of the two solvent supply units 19 are configured by two-fluid nozzles. In this respect, the mist nozzles 29 and 30 may be constituted by one-fluid nozzles. The one-fluid nozzle is a nozzle that makes a liquid into a mist status by the pressure of the liquid without using gas.

(5) In each of the above-described embodiments and modifications, the substrate W is raised to the upper position H2 and then the substrate W is caused to stand by at the upper position H2 in the three substrate lifting operations of FIG. 5. The height position at which the substrate W is caused to stand by on the upper side may not coincide with the upper position H2. The position at which the substrate W is caused to stand by on the upper side may be, for example, a position H2A near the upper position H2 as illustrated in FIG. 5. In addition, the position at which the substrate W is caused to stand by on the upper side may be a height position where the lower end of the substrate W is accommodated in the processing tank 2. Further, the upper position H2 or the position H2A corresponds to a position at which the substrate of the present invention is raised.

(6) In each of the above-described embodiments and modifications, the substrate W is lowered to the lower position H3 and then the substrate W is caused to stand by at the lower position H3 in the three substrate lifting operations of FIG. 5. The height position at which the substrate W is caused to stand by on the lower side may not coincide with the lower position H3. The position at which the substrate W is caused to stand by on the lower side may be, for example, a position H3A near the position H3 as illustrated in FIG. 5. Further, the lower position H3 or the position H3A corresponds to a position in the processing tank of the present invention.

(7) In each of the above-described embodiments and modifications, the substrate processing device 1 includes the QDR valve 11 that discharges the processing liquid (for example, pure water) from the processing tank 2. In this respect, the substrate processing device 1 may include a discharge pipe extending from the processing tank 2 to the outside of the chamber 3 and an on-off valve provided in the discharge pipe. The processing liquid may be directly discharged from the processing tank 2 to the outside of the chamber 3 by opening the on-off valve without being stored in the bottom portion of the chamber.

(8) In each of the above-described embodiments and modifications, the QDR valve 11 is closed in step S06. In this regard, the QDR valve 11 may be open as long as a relationship is established in which the amount of IPA adhering to the substrate W is larger when the substrate W is disposed at the lower position H3 than when the substrate W is disposed at the upper position H2.

(9) In the first and second embodiments and each modification described above, the two water-repellent agent vapor nozzles 17 supply the water-repellent agent vapor into the chamber 3. Instead of the two water-repellent agent vapor nozzles 17, two nozzle rows may be provided. Each of the two nozzle rows includes a plurality of mist nozzles arranged in the Y direction. The mist nozzles of the two nozzle rows supply a mist-like water-repellent agent into the chamber 3.

The present invention may be embodied in other specific forms without departing from the spirit or essential attributes thereof and, accordingly, reference should be made to the appended claims, rather than to the foregoing specification, as indicating the scope of the invention.

What is claimed is:

1. A substrate processing device for processing a substrate, the substrate processing device comprising:
a processing tank that stores processing liquid;
a chamber that accommodates the processing tank;
a decompression pump that decompresses an inside of the chamber;
a lifter that lifts the substrate up and down in the chamber while holding the substrate;
an on-off valve that discharges the processing liquid from the processing tank;
a solvent supply unit that is provided in the chamber, the solvent supply unit being disposed at a position higher than an opening formed in an upper surface of the processing tank, and supplying at least one of a mist-like solvent and a droplet-like solvent from an outside of the processing tank toward an inside of the processing tank in plan view; and
a control unit, wherein
the control unit performs a solvent supply operation of causing the decompression pump to decompress the inside of the chamber and supplying at least one of the mist-like solvent and the droplet-like solvent from the solvent supply unit when the substrate is immersed in the processing liquid,
the control unit causes the lifter to take out the substrate from the processing liquid in the processing tank in a solvent supply state in which the inside of the chamber is decompressed and the solvent is supplied, and then opens the on-off valve to discharge the processing liquid from the processing tank, and
the control unit performs, in the solvent supply state, a substrate lifting operation of causing the lifter to lower the substrate to a position in the processing tank where the processing liquid is not stored, and then causing the lifter to raise the substrate.

2. The substrate processing device according to claim 1, wherein
the substrate lifting operation causes, in the solvent supply state, the lifter to lower the substrate to a position in the processing tank, makes the lifter to cause the substrate to stand by for a preset lower standby time at a position in the processing tank, then causes the lifter to raise the substrate, and makes the lifter to cause the substrate to stand by for a preset upper standby time at a position at which the substrate is raised, and
the lower standby time is longer than the upper standby time.

3. The substrate processing device according to claim 2, wherein
the substrate lifting operation is performed a plurality of times.

4. The substrate processing device according to claim 1, further comprising:
a water-repellent agent nozzle that supplies water-repellent agent vapor into the chamber, wherein
the control unit causes the water-repellent agent nozzle to supply the water-repellent agent vapor to the substrate after the substrate lifting operation is performed and after supplying of the solvent is stopped.

5. The substrate processing device according to claim 4, wherein
after supplying of the water-repellent agent vapor is stopped, the control unit performs a second solvent supply operation of causing the decompression pump to decompress the inside of the chamber and supplying at least one of the mist-like solvent and the droplet-like solvent from the solvent supply unit.

6. The substrate processing device according to claim 5, wherein the second solvent supply operation is performed when the lifter causes the substrate to stand by at a position in the processing tank where the processing liquid is not stored.

7. The substrate processing device according to claim 5, wherein
when the second solvent supply operation is being performed, the control unit causes the lifter to lower the substrate to a position in the processing tank when the second solvent supply operation is being performed, makes the lifter to cause the substrate to stand by for a preset second lower standby time at a position in the processing tank, then causes the lifter to raise the substrate, and makes the lifter to cause the substrate to stand by for a preset second upper standby time at a position at which the substrate is raised, and
the second lower standby time is longer than the second upper standby time.

8. A substrate processing method of a substrate processing device, the substrate processing device including:
a processing tank that stores processing liquid;
a chamber that accommodates the processing tank;
a decompression pump that decompresses an inside of the chamber;
a lifter that lifts a substrate up and down in the chamber while holding the substrate; and
an on-off valve that discharges the processing liquid from the processing tank,
the substrate processing method comprising:
a solvent supply step of causing the decompression pump to decompress the inside of the chamber and supplying at least one of a mist-like solvent and a droplet-like solvent from a solvent supply unit when the substrate is immersed in the processing liquid;
a substrate extraction step of causing the lifter to take out the substrate from the processing liquid in the processing tank in a solvent supply state in which the inside of the chamber is decompressed and the solvent is supplied;
a processing liquid discharge step of discharging the processing liquid from the processing tank by opening the on-off valve in the solvent supply state and after the substrate extraction step is performed; and
a substrate lifting step of causing the lifter to lower the substrate to a position in the processing tank where the processing liquid is not stored in the solvent supply state, and then causing the lifter to raise the substrate, wherein
the solvent supply unit is provided in the chamber, and
the solvent supply unit is disposed at a position higher than an opening formed in an upper surface of the processing tank, and supplies at least one of the mist-like solvent and the droplet-like solvent from an outside of the processing tank toward an inside of the processing tank in plan view.

9. The substrate processing method according to claim 8, wherein
in the substrate lifting step, in the solvent supply state, the lifter makes the substrate lower to a position in the processing tank, makes the substrate stand by for a preset lower standby time at a position in the processing tank, then raises the substrate, and makes the substrate stand by for a preset upper standby time at a position at which the substrate is raised, and
the lower standby time is longer than the upper standby time.

10. The substrate processing method according to claim 9, wherein
the substrate lifting step is performed a plurality of times.

11. The substrate processing method according to claim 8, further comprising:
a water-repellent agent vapor supply step of supplying water-repellent agent vapor from a water-repellent agent nozzle to the substrate in the chamber after the substrate lifting step is performed and after supplying of the solvent is stopped.

12. The substrate processing method according to claim 11, further comprising:
a second solvent supply step of causing, after supplying of the water-repellent agent vapor is stopped, the decompression pump to decompress the inside of the chamber; and
supplying at least one of the mist-like solvent and the droplet-like solvent from the solvent supply unit.

13. The substrate processing method according to claim 12, wherein
the second solvent supply step is performed when the lifter causes the substrate to stand by at a position in the processing tank where the processing liquid is not stored.

14. The substrate processing method according to claim 12, further comprising:
a second substrate lifting step of causing, when the second solvent supply step is being performed, the lifter to lower the substrate to a position in the processing tank, causing the lifter to make the substrate stand by for a preset second lower standby time at a position in the processing tank, then causing the lifter to raise the substrate, and causing the lifter to make the substrate stand by for a preset second upper standby time at a position at which the substrate is raised,
wherein the second lower standby time is longer than the second upper standby time.
